(19) United States
(12) Patent Application Publication
(10) Pub. No.: US 2026/0190819 A1
(43) Pub. Date: Jul. 2, 2026

(54) DISPLAY SUBSTRATE, DISPLAY APPARATUS AND MANUFACTURING METHOD FOR DISPLAY SUBSTRATE

(71) Applicants: Chengdu BOE Optoelectronics Technology Co., Ltd., Sichuan Province (CN); BOE Technology Group Co., Ltd., Beijing (CN)

(72) Inventors: Haoyu LI, Beijing (CN); Youchun CHEN, Beijing (CN); Hongting LU, Beijing (CN); Yu WU, Beijing (CN); Ling SHI, Beijing (CN)

(21) Appl. No.: 18/841,612

(22) PCT Filed: Sep. 22, 2023
(86) PCT No.: PCT/CN2023/120612

§ 371 Date: Aug. 26, 2024

(51) Int. Cl. H10K 59/80; H10K 59/12; H10K 59/122; H10K 59/35

(52) U.S. Cl. CPC H10K 59/8792; H10K 59/1201; H10K 59/122; H10K 59/352

(57) ABSTRACT

The present disclosure provides a display substrate, a display apparatus and a manufacturing method of a display substrate, including a base substrate; a plurality of sub-pixels are arranged in array on the base substrate, where at least one of the sub-pixels includes at least two light-emitting regions, and light-emitting regions of different sub-pixels are arranged in isolation in the first direction and the second direction, the first direction is an anti-peeping direction, and the second direction is perpendicular to the first direction; and a plurality of light-shielding structures arranged at a light-emitting side of the plurality of sub-pixels, where an orthographic projection of the light-shielding structure on the base substrate extends in the second direction between adjacent light-emitting regions, and the orthographic projection of the light-shielding structure on the base substrate and a corresponding light-emitting region have a first distance in the first direction.

### CROSS REFERENCE TO RELATED APPLICATIONS

The present disclosure is a national phase entry under 35 U.S.C § 371 of International Application No. PCT/CN2023/120612, filed Sep. 22, 2023, the entire content of which is incorporated herein by reference.

### TECHNICAL FIELD

The present disclosure relates to the field of display technologies, in particular to a display substrate, a display apparatus and a manufacturing method for a display substrate.

### BACKGROUND

With the development of society, people's demand for the application scenarios of display products is more and more extensive, and the demand for in-vehicle display is getting higher and higher. However, the large viewing angle of the light projected onto the reflector or front windshield will affect the driver's vision during normal driving.

### SUMMARY

Embodiments of the present disclosure provide a display substrate, a display apparatus and a manufacturing method for a display substrate, and include a specific solution as follows.

In an aspect, the embodiments of the present disclosure provide a display substrate, including a base substrate, a plurality of sub-pixels and a plurality of light-shielding structures. The plurality of sub-pixels is arranged on the base substrate in an array. At least one of the sub-pixels includes at least two light-emitting regions, and light-emitting regions of different sub-pixels are arranged in isolation in a first direction and in a second direction, respectively. The first direction is an anti-peeping direction, and the second direction is perpendicular to the first direction. The plurality of light-shielding structures is arranged at a light emitting side of the plurality of sub-pixels. An orthographic projection of the light-shielding structure on the base substrate extends along the second direction between adjacent light-emitting regions. The orthographic projection of the light-shielding structure on the base substrate has a first distance from a corresponding light-emitting region in the first direction.

In some embodiments, in the above display substrate provided by the embodiments of the present disclosure, different sub-pixels in a part of the sub-pixels includes different quantities of light-emitting regions.

In some embodiments, in the above display substrate provided by the embodiments of the present disclosure, in a sub-pixel including a plurality of light-emitting regions, the plurality of light-emitting regions in the sub-pixel are arranged side by side and isolated from each other in the first direction.

In some embodiments, in the above display substrate provided by the embodiments of the present disclosure, sub-pixels in a row along the second direction each includes a same quantity of light-emitting regions; and the plurality of light-shielding structures includes a plurality of first light-shielding structures, and orthographic projections of the first light-shielding structures on the base substrate are continuously arranged in the second direction between light-emitting regions of sub-pixels in the row.

In some embodiments, in the above display substrate provided by the embodiments of the present disclosure, a part of the sub-pixels in a row along the second direction each includes multiple light-emitting regions of a same quantity, and the rest of the sub-pixels in the row each includes one light-emitting region. The plurality of light-shielding structures includes a plurality of second light-shielding structures, and an orthographic projection of the second light-shielding structure on the base substrate extends in the second direction between light-emitting regions of the part of sub-pixels in the row, and is disconnectedly arranged at regions where the rest of the sub-pixels are located.

In some embodiments, in the above display substrate provided by the embodiments of the present disclosure, the plurality of light-shielding structures includes a plurality of third light-shielding structures. Orthographic projections of the third light-shielding structures on the base substrate are continuously arranged in the second direction between adjacent sub-pixels.

In some embodiments, in the above display substrate provided by the embodiments of the present disclosure, the sub-pixel further includes a pixel circuit and a light emitting element. An insulating layer is disposed between a layer where the pixel circuit is located and a layer where the light emitting element is located. In the same one sub-pixel, the pixel circuit is electrically connected with the light emitting element through a via hole penetrating through the insulating layer. An orthographic projection of the via hole on the base substrate is within the orthographic projection of the third light-shielding structure on the base substrate.

In some embodiments, in the above display substrate provided by the embodiments of the present disclosure, at least part of the light-emitting regions in a plurality of light-emitting regions of the same one sub-pixel have substantially a same size in the first direction. In different sub-pixels each including a plurality of light-emitting regions, at least part of the light-emitting regions have substantially a same size in the first direction.

In some embodiments, in the above display substrate provided by the embodiments of the present disclosure, a light-emitting region of a sub-pixel including only the light-emitting region has a size in the first direction that is greater than a size, in the first direction, of a light-emitting region of a sub-pixel including a plurality of light-emitting regions.

In some embodiments, in the above display substrate provided by the embodiments of the present disclosure, a quantity of light-emitting regions of the part of the sub-pixels is greater than a quantity of light-emitting regions of the rest of the sub-pixels. A color of light emitted by the part of the sub-pixels is different from a color of light emitted by the rest of the sub-pixels.

In some embodiments, in the above display substrate provided by the embodiments of the present disclosure, the plurality of sub-pixels includes a plurality of first sub-pixels, a plurality of second sub-pixels, and a plurality of third sub-pixels. Luminous brightness of the first sub-pixels and luminous brightness of the second sub-pixels each is greater than luminous brightness of the third sub-pixels. The first sub-pixel and/or the second sub-pixel each includes a plurality of the light-emitting regions, and the third sub-pixel includes one light-emitting region.

In some embodiments, in the above display substrate provided by the embodiments of the present disclosure, one of the first sub-pixel and the second sub-pixel is arranged alternately with the third sub-pixel in the second direction, and a row where the other one of the first sub-pixel and the second sub-pixel is located and a row where the third sub-pixel is located are arranged alternately in the first direction.

In some embodiments, in the above display substrate provided by the embodiments of the present disclosure, among the first sub-pixel, the second sub-pixel and the third sub-pixel, a size, in the second direction, of a light-emitting region of the first sub-pixel or the second sub-pixel in a separate row is larger than a size, in the second direction, of a light-emitting region of each of the remaining two sub-pixels.

In some embodiments, in the above display substrate provided by the embodiments of the present disclosure, the first sub-pixels are arranged alternately with the second sub-pixels in the second direction. Rows in which the first sub-pixels are located are arranged alternately in the first direction with rows in which the third sub-pixels are located; or rows in which the first sub-pixels are located, rows in which the second sub-pixels are located, and rows in which the third sub-pixels are located are arranged alternately and cyclically in the second direction.

In some embodiments, in the above display substrate provided by the embodiments of the present disclosure, the first sub-pixel is a red sub-pixel, the second sub-pixel is a green sub-pixel, and the third sub-pixel is a blue sub-pixel.

In some embodiments, in the above display substrate provided by the embodiments of the present disclosure, the sub-pixel further includes an anode, and the anode is integrally arranged within the sub-pixel.

In some embodiments, in the above display substrate provided by the embodiments of the present disclosure, the sub-pixel further includes a light emitting material layer on a side of the anode away from the base substrate, and the light emitting material layer is disconnectedly arranged between a plurality of light-emitting regions in the sub-pixel.

In some embodiments, the above display substrate provided by the embodiments of the present disclosure further includes a pixel definition layer between a layer where the anode is located and the light emitting material layer. The pixel definition layer includes a plurality of openings, and regions where the openings are located are the light-emitting regions.

In another aspect, the embodiments of the present disclosure provided a display apparatus, including the above display substrate provided by the embodiments of the present disclosure. The display apparatus includes an instrument panel, and the anti-peeping direction is a vertical direction.

In another aspect, the embodiments of the present disclosure provided a manufacturing method of a display substrate, including:
providing a base substrate;
forming a plurality of sub-pixels arranged on the base substrate in an array; where at least one of the sub-pixels includes at least two light-emitting regions, light-emitting regions of different sub-pixels are arranged in isolation in a first direction and a second direction, respectively, and the first direction is an anti-peeping direction, and the second direction is perpendicular to the first direction;
forming a plurality of light-shielding structures on a side of a layer where the plurality of sub-pixels are located away from the base substrate; where an orthographic projection of the light-shielding structure on the base substrate extends in the second direction between adjacent the light-emitting regions, and the orthographic projection of the light-shielding structure on the base substrate has a first distance from a corresponding light-emitting region in the first direction.

### BRIEF DESCRIPTION OF FIGURES

FIG. 1 is a schematic structural diagram of a display substrate provided by embodiments of the present disclosure.

FIG. 2 is an enlarged schematic diagram of region Z of FIG. 1.

FIG. 3 is a sectional view along the direction I-I′ in FIG. 2.

FIG. 4 is an anti-peeping light emitting diagram in the direction II-II′ in FIG. 2.

FIG. 5 is a normal light emitting diagram in the direction III-III′ in FIG. 2.

FIG. 6 is a brightness simulation diagram of a display substrate provided by embodiments of the present disclosure in region A+.

FIG. 7 is a brightness simulation diagram of a display substrate provided by embodiments of the present disclosure in region A.

FIG. 8 is a brightness simulation diagram of a display substrate provided by embodiments of the present disclosure in region B.

FIG. 9 is yet another schematic structural diagram of a display substrate provided by embodiments of the present disclosure.

FIG. 10 is yet another schematic structural diagram of a display substrate provided by embodiments of the present disclosure.

FIG. 11 is yet another schematic structural diagram of a display substrate provided by embodiments of the present disclosure.

FIG. 12 is yet another schematic structural diagram of a display substrate provided by embodiments of the present disclosure.

FIG. 13 is yet another schematic structural diagram of a display substrate provided by embodiments of the present disclosure.

FIG. 14 is yet another schematic structural diagram of a display substrate provided by embodiments of the present disclosure.

FIG. 15 is yet another schematic structural diagram of a display substrate provided by embodiments of the present disclosure.

FIG. 16 is a schematic structural diagram of a display apparatus provided by embodiments of the present disclosure.

FIG. 17 is a flow chart of the fabrication of a display substrate provided by the embodiments of the present disclosure.

### REFERENCE NUMERALS

101—base substrate; 102—sub-pixel; 1021—first sub-pixel; 1022—second sub-pixel; 1023—third sub-pixel; 103—pixel definition layer; 104—light-shielding structure; 1041—first light-shielding structure; 1042—second light-shielding structure; 1043—third light-shielding structure; 105—first pole; 106—light emitting functional layer; 107—encapsulation layer; 108—second pole; 10—sub-pixels array; 20—timing controller; 30—scanning driver; 40—data driver.

### DETAILED DESCRIPTION

For making objectives, technical solutions and advantages of embodiments of the present disclosure clearer, the technical solutions of the embodiments of the present disclosure will be clearly and completely described below in conjunction with the drawings in the embodiments of the present disclosure. It should be noted that in the drawings, the thickness of layer, the thickness of film, the thickness of panel, the thickness of area, etc. are enlarged for clarity. Exemplary embodiments are described in the present disclosure with reference to a cross-sectional view as a schematic diagram of an idealized embodiment. In this way, deviations from the shape of the drawing as a result of, for example, manufacturing techniques and/or tolerances will be expected. Thus, the embodiments described in the present disclosure should not be construed to be limited to specific shapes of regions as shown in the present disclosure, but rather to include deviations in shape caused by, for example, manufacturing. For example, regions illustrated or described as flat may typically have rough and/or non-linear features; sharp corners illustrated may be rounded, etc. Thus, the regions shown in the drawings are schematic in nature, and their dimensions and shapes do not purport to be the precise shape of the illustrated regions, do not reflect true scales, and are intended only to illustrate the present disclosure schematically. And throughout the drawings, identical or similar reference numerals denote identical or similar elements or elements having identical or similar functions. To keep the following description of the embodiments of the present disclosure clear and concise, detailed descriptions of known functions and components are omitted in the present disclosure.

Unless otherwise defined, technical or scientific terms used herein should have ordinary meanings as understood by those of ordinary skill in the art to which the present disclosure belongs. “First”, “second” and other similar words used in the description and claims of the present disclosure do not indicate any order, amount or importance, but only for distinguishing different components. “Include” or, “comprise” and other similar words indicate that elements or objects before the word include elements or objects after the word and their equivalents, without excluding other elements or objects. “Connection” or “coupling” and other similar word is not restricted to physical or mechanical connection, but may include electrical connection, whether direct or indirect. “Inside”, “outside”, “up”, “down”, etc. are only used to indicate a relative positional relation, and when the absolute position of the described object changes, the relative positional relationship may change accordingly.

In the following description, when an element or layer is referred to be “on” or “connected to” another element or layer, the element or layer may be directly on, directly connected to, or may have an intermediate element or intermediate layer. When the element or layer is referred to be “arranged on a side” of another element or layer, the element or layer may be directly on the side of the other element or layer, directly connected to the other element or layer, or there may be an intermediate element or intermediate layer. However, when the element or layer is said to be “directly on” the other element or layer, “directly connected to” the other element or layer, there is no intermediate element or intermediate layer. The term “and/or” includes any and all combinations of one or more relevant listings.

Related vehicle display products use an external privacy filter when performing anti-peeping, but there will be a problem of low display brightness, which is easy to cause visual fatigue, and at the same time, in order to achieve the appropriate display brightness, it often causes increased power consumption.

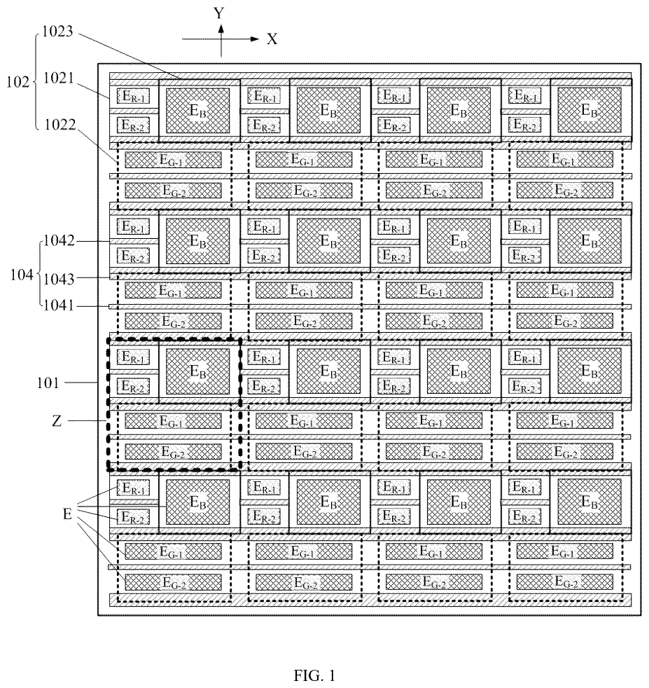

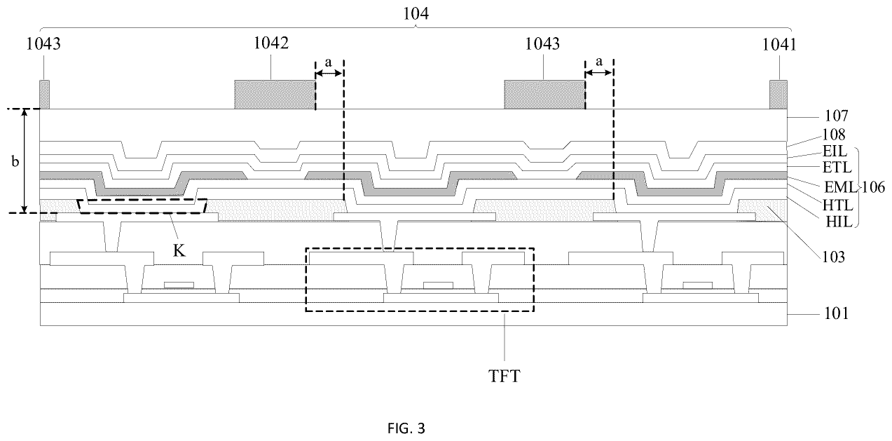

In order to solve the above technical problems existing in the related art, embodiments of the present disclosure provide a display substrate, as shown in FIG. 1 to FIG. 3, which may include a base substrate 101, a plurality of sub-pixels 102 and a plurality of light-shielding structure 104.

In some embodiments, the base substrate 101 may be a flexible substrate, or may be a rigid substrate. For example, the rigid substrate may include a glass substrate, a quartz substrate, and the like. The flexible substrate may include a first flexible material layer, a first inorganic material layer, a semiconductor layer, a second flexible material layer and a second inorganic material layer which are stacked. The material of the first flexible material layer and the second flexible material layer may be a polyimide (PI), a polyethylene terephthalate (PET), or a polymer flexible film treated with a surface treatment, etc. The material of the first inorganic material layer and the second inorganic material layer may be silicon nitride (SiNx) or silicon oxide (SiOx), etc., for improving the hydroxide resistance of the base substrate. The material of the semiconductor layer may be amorphous silicon (a-Si).

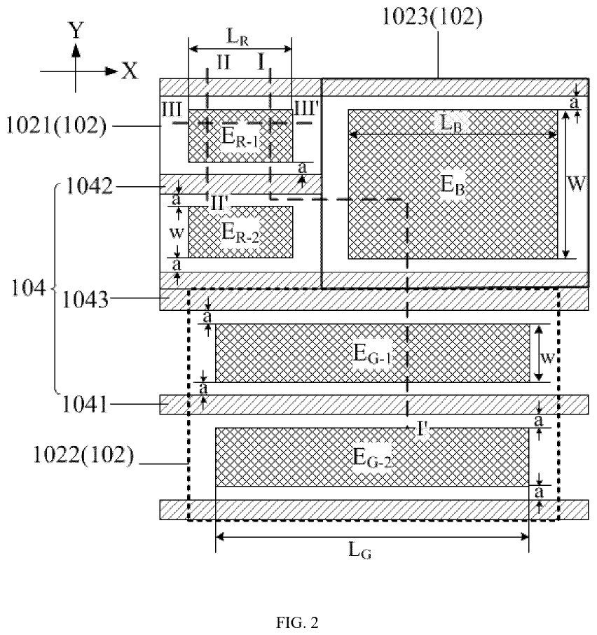

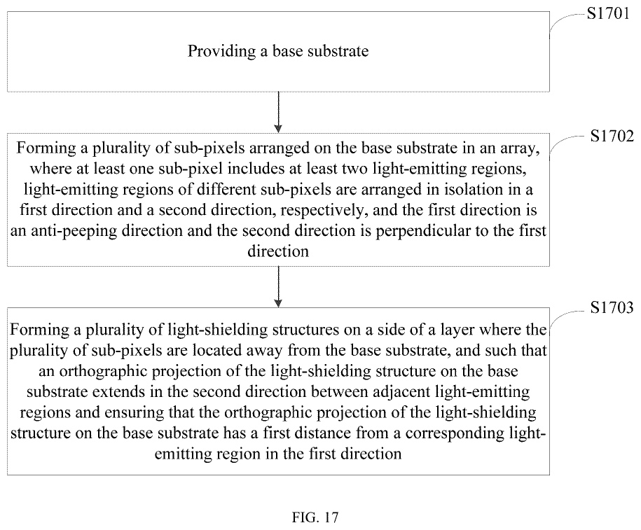

The plurality of sub-pixels 102 are arranged on the base substrate 101 in an array, optionally, FIG. 1 is illustrated with a 4*4 array as an example. In some embodiments, the plurality of sub-pixels 102 may include a plurality of first sub-pixels 1021, a plurality of second sub-pixels 1022, and a plurality of third sub-pixels 1023. Optionally, the first sub-pixel 1021 is a red sub-pixel R, the second sub-pixel 1022 is a green sub-pixel G, and the third sub-pixel 1023 is a blue sub-pixel B; and of course, in other embodiments, the plurality of sub-pixels 102 may also include yellow sub-pixels, white sub-pixels, and the like, without specific limitation herein. Continuing to refer to FIG. 1 and FIG. 2, it can be seen that the at least one of the sub-pixels 102 includes at least two light-emitting regions E. For example, the first sub-pixel 1021 includes two light-emitting regions E labeled as E_{R-1} and E_{R-2}, respectively, the second sub-pixel 1022 includes two light-emitting regions E labeled as E_{G-1} and E_{G-2}, respectively, and the third sub-pixel 1023 includes one light-emitting region E labeled as EB. Of course, in a specific implementation, the first sub-pixel 1021, the second sub-pixel 1022, and the third sub-pixel 1023 include light-emitting regions E that are not limited to the above quantity. In some embodiments, in order to avoid outgoing light crosstalk, light-emitting regions E of the different sub-pixels 102 may be arranged in isolation in the first direction Y and the second direction X, the first direction Y is the anti-peeping direction, and the second direction X is perpendicular to the first direction Y. For example, the display substrate provided by the present disclosure may be applied to the instrument panel shown in FIG. 16, which is usually located in front of the driver, and the anti-peep direction (i.e., the first direction Y) is the vertical direction in FIG. 16. In some embodiments, the light-emitting region E may be equivalent to a region where an opening K of a pixel definition layer 103 is located, and different light-emitting regions E may be separated from each other by the pixel definition layer 103. In some embodiments, the pixel definition layer 103 may be made of an organic material, such as a polyimide, an acrylic, a polyethylene terephthalate, or an acrylate.

Continuing to refer to FIG. 1 to FIG. 3, it can be seen that the plurality of light-shielding structures 104 are arranged at a light emitting side of the plurality of sub-pixels 102. Optionally, the light-shielding structures 104 are fabricated using a black matrix (BM) material. In some embodiments, an orthographic projection of the light-shielding structure 104 on the base substrate 101 extends along a second direction X between adjacent light-emitting regions E; for example, in the present disclosure, the light-shielding structure 104 is arranged only at a gap extending along the second direction X between adjacent light-emitting regions E, and the light-shielding structure 104 is not arranged at a gap extending along the first direction Y between adjacent light-emitting regions E. In some embodiments, the orthographic projection of the light-shielding structure 104 on the base substrate 101 has a first distance a from a corresponding light-emitting region E in the first direction Y, and the first distance a is positively correlated to the anti-peeping angle, so that the light-shielding structure 104 can achieve a better anti-peeping effect at a specific viewing angle (e.g., ±30°) by setting a value of the first distance a.

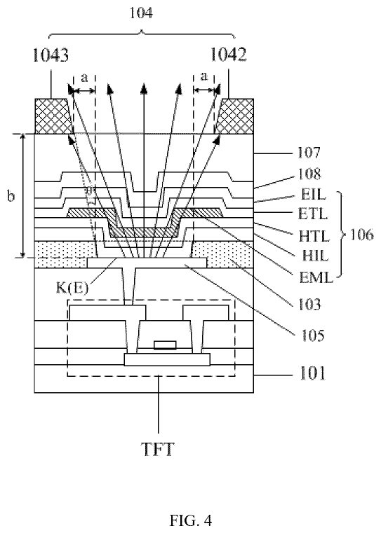

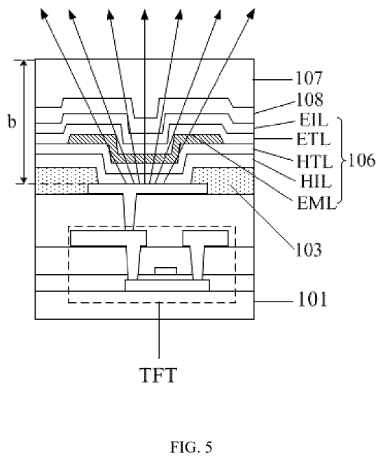

In the above display substrate provided by embodiments of the present disclosure, by providing at least part of the sub-pixels 102 each including a plurality of light-emitting regions E, and by providing a light-shielding structure 104 between the light-emitting regions E of different sub-pixels 102 and providing a light-shielding structure 104 between the light-emitting regions E of the same sub-pixel 102, the light-shielding structure 104 can be made to realize the anti-peeping effect at the first distance a in the first direction Y, and the specific principle is shown in FIG. 4. In FIG. 4, a represents the first distance between the above-mentioned light-shielding structure 104 and the light-emitting region E, and b represents a vertical height from a layer where a first pole (e.g., anode) 105 is located to a layer where the light-shielding structure 104 is located, and optionally, b is equal to a sum of a thickness of the pixel definition layer 103, a thickness of the light emitting functional layer 106, and a thickness of a encapsulation layer 107 minus a thickness of the first pole 105. At this time, it is possible to calculate the tangent value a/b of the maximum light output direction (i.e., the anti-peep angle θ, which can be set according to actual needs, for example, θ is ±30°) according to the Pythagorean theorem, i.e., a/b=tanθ, in other words a=b*tan θ. It should be understood that, in some embodiments, there may be other film layers such as a planarization layer (i.e., overcoat (OC)) between the encapsulation layer 107 and the layer in which the light-shielding structure 104 is located. In this case, the value of b is equal to the previously calculated value of b plus the thickness of the other film layer such as the planarization layer (OC). Since thin and light display products are a development trend, a large value of b is not conducive to the thin and light design of the display products, therefore, the present disclosure maintains the value of b in the related products, and the anti-peeping effect can be realized by adjusting the value of a. As verified by the inventor, the anti-peeping effect is better when the first distance a is in the range of 2 μm˜6 μm. In some embodiments, the first distance a may be 2 μm, 3 μm, 4 μm, 5 μm, 6 μm, etc. In addition, FIG. 5 illustrates a schematic diagram in which the display substrate normally emits light in the second direction X. Since the light-shielding structure 104 is not arranged in the second direction X, the light in the second direction X is not blocked and normal large-angle light output can be realized.

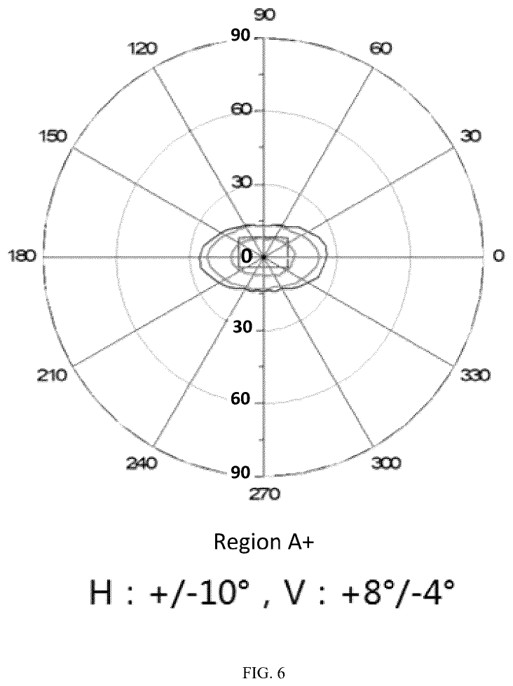

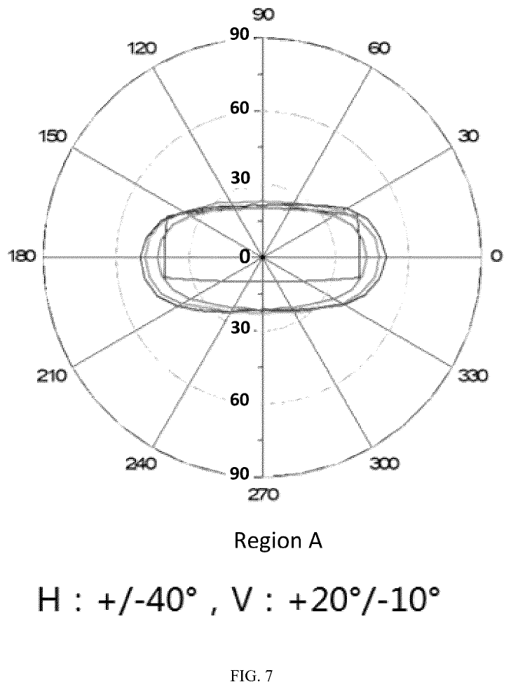

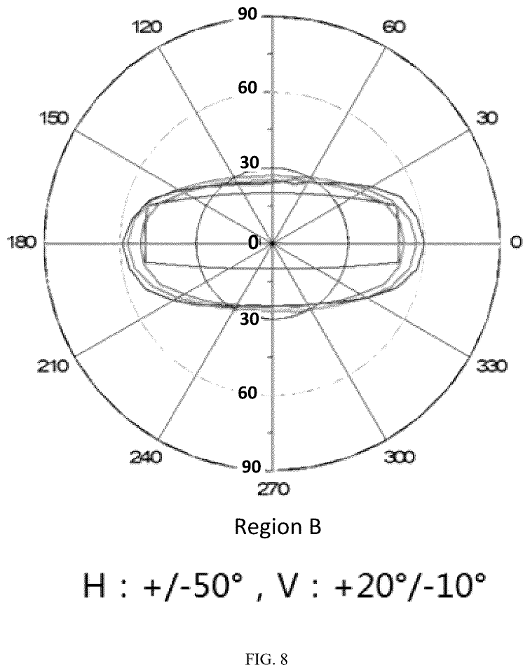

FIG. 6 shows a brightness simulation diagram in the range of −10° to +10° in the first direction Y, and in the range of −4° to +8° in the second direction X (i.e., region A+), FIG. 7 shows a brightness simulation diagram in the range of −40° to +40° in the first direction Y, and in the range of −10° to +20° in the second direction X (i.e., region A), and FIG. 8 shows a brightness simulation diagram in the range of −50° to +50° in the first direction Y, and in the range of −10° to +20° in the second direction X (i.e., region B). Table 1 shows the luminance values of the positive viewing angle, region A+, region A, and region B in Schemes 1, 2, and 3 for which the values of a are fixed (e.g., 4 μm) and the values of b are different (specifically, because of the thickness of the encapsulation layer changes). As seen in Table 1, the luminance values of the positive viewing angle, region A+, region A, and region B in Scheme 1 are 1000 nit, 946 nit, 422 nit, and 312 nit, respectively; the luminance values of the positive viewing angle, region A+, region A, and region B in Scheme 2 are 1000 nit, 788 nit, 301 nit, and 215 nit, respectively; and the luminance values of the positive viewing angle, region A+, region A, and region B in Scheme 3 are 1234 nit, 972 nit, 371 nit, 265 nit, respectively; it can be seen that the luminance values of the positive viewing angle, region A+, region A, and region B in each of Schemes 1-3 are all decreasing sequentially. As the viewing angle range of the positive viewing angle, the region A+, the region A, and the region B in the first direction Y increases sequentially, the luminance values of the positive viewing angle, the region A+, the region A, and the region B decrease sequentially, which is equivalent to the luminance of the large viewing angle range (e.g., ±50°˜±40°) is lower, thus realizing a better large-viewing-angle anti-peeping effect.

TABLE 1

| | positive viewing | | | |
|---|---|---|---|---|
| | angle | Region A+ | Region A | Region B |
| Scheme 1 | 1000 nit | 946 nit | 422 nit | 312 nit |
| Scheme 2 | 1000 nit | 788 nit | 301 nit | 215 nit |
| Scheme 3 | 1234 nit | 972 nit | 371 nit | 265 nit |

As can be seen from the above, the present disclosure realizes a good anti-peeping effect in the first direction Y by providing a light-shielding structure 104 between the light-emitting regions E that extends along the second direction X and has a first distance a from the light-emitting regions E. Moreover, since the light-shielding structure 104 that extends along the first direction Y is not arranged between the light-emitting regions E, the light-emitting regions E emit light normally in the second direction X for display. Based on this, the present disclosure does not require the external application of a privacy filter, thereby avoiding the problems of low display brightness, easy visual fatigue, and high power consumption caused by the external application of the privacy filter.

In some embodiments, as shown in FIG. 4, the light-emitting functional layer 106 may include, but is not limited to, a hole injection layer (HIL), a hole transport layer (HTL), an emitting material layer (EML, Emitting Layer), an electron transport layer (ETL), and an electron injection layer (EIL). In other embodiments, the light-emitting functional layer 106 may also include an electron block layer (EBL) between the hole transport layer HTL and the light-emitting material layer EML, and a hole block layer (HBL) between the electron transport layer ETL and the light-emitting material layer EML. In some embodiments, the light-emitting material layer EML of each sub-pixel 102 is arranged disconnected between different light-emitting regions E. The hole injection layers HIL of all sub-pixels 102 may be common layers connected together, the electron injection layers EIL of all sub-pixels 102 may be common layers connected together, the hole transport layers HTL of all sub-pixels 102 may be common layers connected together, and the electron transport layer ETL of all sub-pixels 102 may be common layers connected together, the hole block layers HBL of all sub-pixels 102 may be common layers connected together, and the electron block layers EBL of adjacent sub-pixels 102 may be partially overlapped or may be isolated.

In some embodiments, the encapsulation layer 107 may include a first encapsulation layer, a second encapsulation layer, and a third encapsulation layer set in a cascade. The first encapsulation layer and the third encapsulation layer may be made of an inorganic material (CVD), and the second encapsulation layer may be made of an organic material (IJP), and the second encapsulation layer may be disposed between the first encapsulation layer and the third encapsulation layer, which ensures that external vapor cannot enter the light emitting functional layer 106. In some other embodiments, the encapsulation layer 107 may adopt a laminated structure of inorganic material/organic material/inorganic material/organic material/inorganic material.

In some embodiments, in the above display substrate provided by embodiments of the present disclosure, as shown in FIG. 2, among the plurality of light-emitting regions E of the same sub-pixel 102, at least part of the light-emitting regions E have substantially the same size w in the first direction Y; optionally, among the plurality of light-emitting regions E of the same sub-pixel 102, all of the light-emitting regions E have substantially the same size w in the first direction Y. Exemplarily, FIG. 2 illustrates that two light-emitting regions E labeled as E_{R-1} and E_{R-2}, respectively, in the first sub-pixel 1021 have substantially the same size w in the first direction Y; and two light-emitting regions E labeled as E_{G-1} and E_{G-2}, respectively, in the second sub-pixel 1022 have substantially the same size w in the first direction Y. By providing a sub-pixel 102 including a plurality of light-emitting regions E in equal parts, the design and process monitoring are facilitated. In some embodiments, the size w of the light-emitting region E in the first direction Y may be determined by the effect of the anti-peeping simulation, for example, if the size w of the light-emitting region E in the first direction Y is 10 μm, the anti-peeping effect obtained after simulating the display is better, so the size w of the light-emitting region E in the first direction Y may be set to be equal to 10 μm.

In some embodiments, in the above display substrate provided by embodiments of the present disclosure, as illustrated in FIG. 2, at least part of the light-emitting regions E have substantially the same sizes w in the first direction Y in different sub-pixels 102 each including the plurality of light-emitting regions E. Optionally, the sizes w of all of the light-emitting regions E in the first direction Y are substantially the same in the different sub-pixels 102 each including the plurality of light-emitting regions E. Exemplarily, FIG. 2 illustrates that the two light-emitting regions E respectively labeled as E_{R-1} and E_{R-2} in the first sub-pixel 1021, and the two light-emitting regions E respectively labeled as E_{G-1} and E_{G-2} in the second sub-pixel 1022 have substantially the same size w in the first direction Y. By splitting each of the different sub-pixels 102 into a plurality of light-emitting regions E according to certain size criteria, it is easy to design and monitor the process.

It should be noted that in the embodiments provided by the present disclosure, due to the limitations of the process conditions or the influence of other factors such as measurement, the “substantially the same” may be exactly the same, or there may be some deviation. Therefore, the relationship of “substantially the same” between the above features falls within the scope of protection of the present disclosure as long as an error (e.g., a variation of 10% up or down) is allowed.

In some embodiments, in the above display substrate provided by embodiments of the present disclosure, as shown in FIG. 2, the size W of the light-emitting region E of the sub-pixel 102 including only one light-emitting region E is larger than the size w of the light-emitting region E of the sub-pixel 102 including a plurality of light-emitting regions E in the first direction Y. As can be seen in FIG. 2, the first sub-pixel 1021 has two light-emitting regions E labeled as E_{R-1} and E_{R-2}, respectively, the second sub-pixel 1022 has two light-emitting regions E labeled as E_{G-1} and E_{G-2}, respectively, and the third sub-pixel 1023 has one light-emitting region E labeled as EB, i.e., in FIG. 2, both the first sub-pixel 1021 and the second sub-pixel 1022 are split and the third sub-pixel 1023 is not split, and therefore, a size w of the light-emitting region E of the third sub-pixel 1023 labeled as EB in the first direction Y is larger than the sizes w, in the first direction Y, of the two light-emitting regions E respectively labeled as E_{R-1} and E_{R-2} in the first sub-pixel 1021, and is also larger than the sizes w of the two light-emitting regions respectively E labeled as E_{G-1} and E_{G-2} in the second sub-pixel 1022 in the first direction Y.

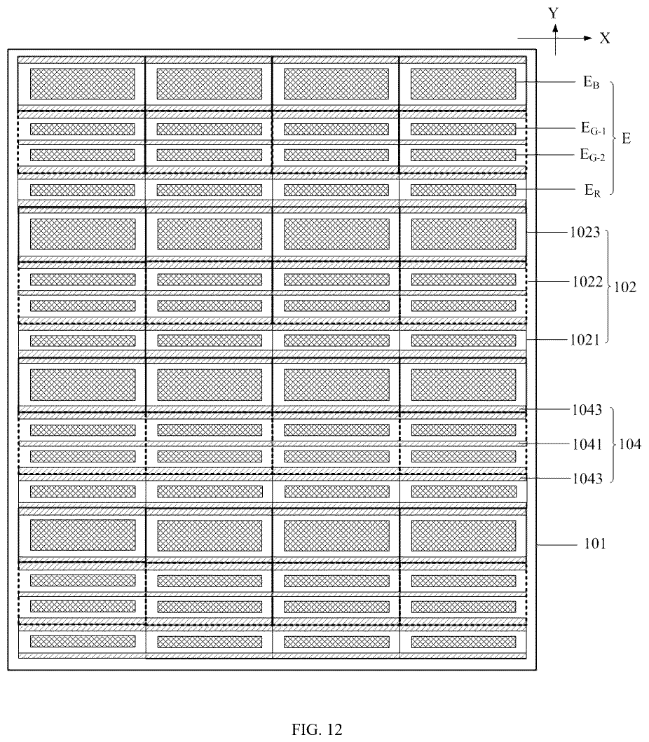

Continuing to refer to FIG. 2, it can be seen that in the above display substrate provided by embodiments of the present disclosure, the quantity of light-emitting regions E of some of the sub-pixels 102 (e.g., the first sub-pixel 1021, the second sub-pixel 1022) is greater than the quantity of light-emitting regions E of the rest of the sub-pixels 102 (e.g., the third sub-pixel 1023), and the color of the light emitted by some of the sub-pixels 102 (e.g., the first sub-pixel 1021, the second sub-pixel 1022) is different from the color of light emitted by the rest of the sub-pixels 102 (e.g., the third sub-pixel 1023). Since the sub-pixels 102 are split according to a certain size (e.g., 10 μm) in the present disclosure, the size of the light-emitting region E of the sub-pixels 102 may be different before the splitting, and thus the sub-pixels 102 emitting light with different colors may include light-emitting regions E in different quantities after the splitting. For example, a size of the light-emitting region E of the second sub-pixel R may be larger than that of the first sub-pixel 1021 and smaller than that of the third sub-pixel 1023 before the splitting, and the quantity of light-emitting regions E of the second sub-pixel R is greater than the quantity of light-emitting regions E of the first sub-pixel 1021 and less than the quantity of light-emitting regions E of the third sub-pixel 1023. Alternatively, the size of the light-emitting region E of the sub-pixel 102 before splitting may be smaller than the splitting criterion, and thus the sub-pixel 102 does not need to be split, for example, as shown in FIG. 12, the size of the light-emitting region E labeled as E_{R} in the first sub-pixel 1021 before splitting is smaller than the splitting criterion, and thus the first sub-pixel 1021 is not split. All of these cases result in different quantities of light-emitting regions E ultimately included in the sub-pixels 102 that emit light of different colors, and the phenomenon that the quantity of light-emitting regions E of some sub-pixels 102 (e.g., the first sub-pixel 1021, the second sub-pixel 1022) is larger than the quantity of light-emitting regions E of the rest of sub-pixels 102 (e.g., the third sub-pixel 1023) occurs.

In other embodiments, the greater the luminous brightness, the greater the impact on the driver's vision of the light reflected back by the reflector or the front windshield, therefore, the luminous brightness can also be used as another criterion to split the sub-pixels 102 in the present disclosure, for example, the luminous brightness of the first sub-pixel 1021 and the luminous brightness of the second sub-pixel 1022 are both greater than that of the third sub-pixel 1023, and the first sub-pixel 1021 and/or the second sub-pixel 1022 may be split without splitting the third sub-pixel 1023, such that the first sub-pixel 1021 and/or the second sub-pixel 1022 each include a plurality of light-emitting regions E, and the third sub-pixel 1023 includes one light-emitting region E. Exemplarily, in FIG. 1 and FIGS. 9-11, both the first sub-pixel 1021 and the second sub-pixel 1022 are split, while the third sub-pixel 1023 is not split. And since the third sub-pixel 1023 has a low brightness, the anti-peeping effect will not be affected even if it is not split.

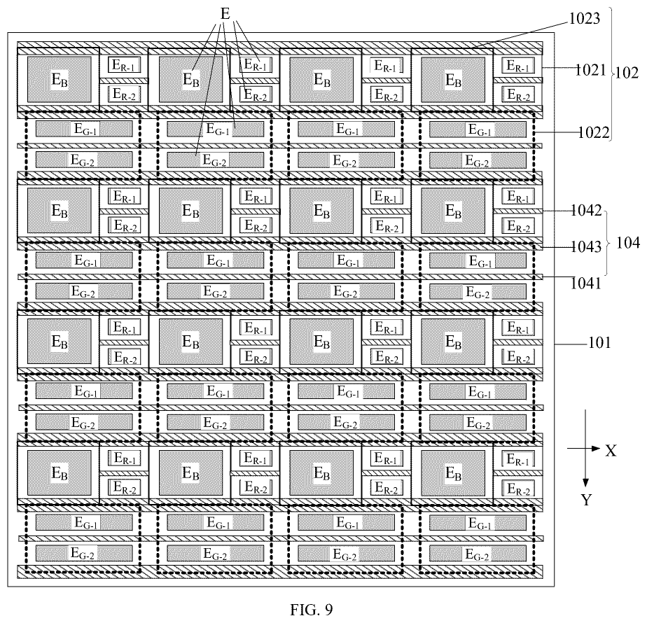

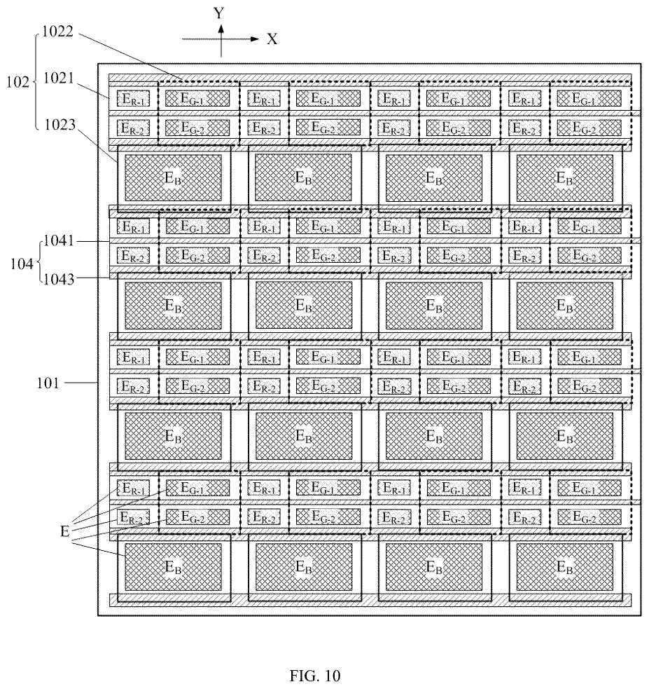

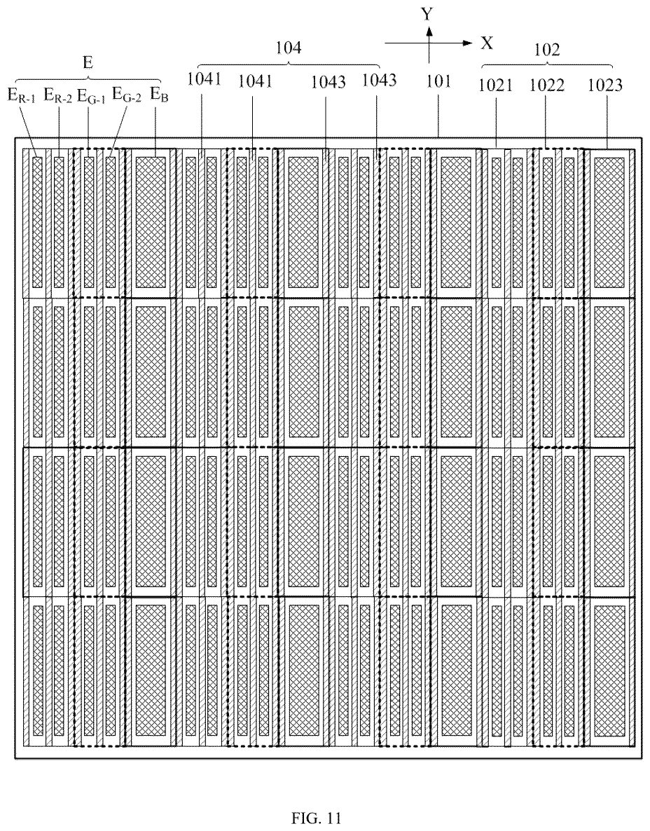

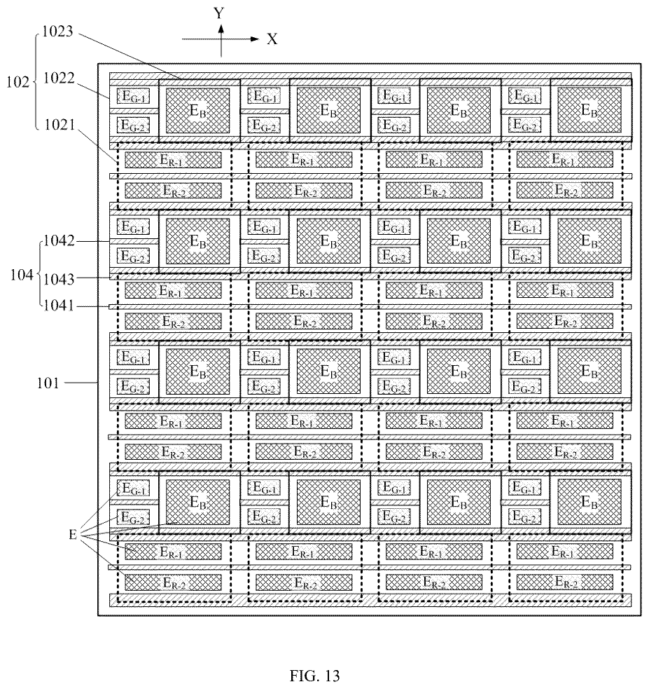

In some embodiments, the arrangement of the first sub-pixel 1021, the second sub-pixel 1022, and the third sub-pixel 1023 in the above display substrate provided by embodiments of the present disclosure may be various. For example, in FIG. 1 and FIG. 9, the first sub-pixels 1021 and the third sub-pixels 1023 may be arranged alternately in the second direction X, and rows in which the first sub-pixels 1021 are located and rows in which the second sub-pixels 1022 are located may be arranged alternately in the first direction Y, so that the first sub-pixel 1021, the second sub-pixel 1022, and the third sub-pixel 1023 are arranged in a shape formed by three rectangles arranged in two adjacent rows in the second direction X, respectively, herein two of the three rectangles are located in the same row and the other one rectangle is located in another row, a region where the sub-pixels with a same color corresponds to one rectangle, and orthographic projections of the two rectangles in the first direction Y overlaps with an orthographic projection of the other one rectangle in the first direction Y. As another example, in FIG. 10, the first sub-pixels 1021 and the second sub-pixels 1022 are arranged alternately in the second direction X, and rows in which the first sub-pixel 1021 are located and rows in which the third sub-pixels 1023 are located are arranged alternately in the first direction Y. At this time, the first sub-pixel 1021, the second sub-pixel 1022, and the third sub-pixel 1023 are also arranged in the shape formed by three rectangles arranged in two adjacent rows in the second direction X, respectively. For another example, as shown in FIGS. 11-12, rows in which the first sub-pixels 1021 are located, rows in which the second sub-pixels 1022 are located, and rows in which the third sub-pixel 1023 are located are arranged alternately and cyclically in the second direction X, such that the first sub-pixel 1021, the second sub-pixel 1022, and the third sub-pixel 1023 are arranged in parallel in the second direction X. In other embodiments, as shown in FIG. 13, the second sub-pixels 1022 and the third sub-pixels 1023 may be arranged alternately in the second direction X, and rows in which the first sub-pixels 1021 are located and rows in which the third sub-pixels 1023 are located may be arranged alternately in the first direction Y, such that the first sub-pixel 1021, the second sub-pixel 1022, and the third sub-pixel 1023 are also arranged in the shape formed by three rectangles arranged in two adjacent rows in the second direction X, respectively. Of course, in specific implementation, the first sub-pixel 1021, the second sub-pixel 1022 and the third sub-pixel 1023 may also be arranged in other arrangements known to those skilled in the art, which are not limited herein.

It is worth noting that, as can be seen in combination with FIGS. 1-2 and FIG. 9, the first sub-pixel 1021 and the third sub-pixel 1023 are in the same row, and the second sub-pixel 1022 is in a separate row, so that it is convenient to set the size LG of the light-emitting region E of the second sub-pixel 1022 in the second direction X to be larger than the size L_{R} of the light-emitting region E of the first sub-pixel 1021 in the second direction X and the size L_{B} of the light-emitting region E of the third sub-pixel 1023 in the second direction X. As such, the opening of the second sub-pixel 1022 can be maximized to reduce the decrease in the aperture ratio due to the splitting of the second sub-pixel 1022 into a plurality of light-emitting regions E, so as to achieve the purpose of increasing the lifespan. For example, the size LG of the light-emitting region E of the second sub-pixel 1022 in the second direction X is smaller than the sum of the size L_{R} of the light-emitting region E of the first sub-pixel 1021 in the second direction X and the size L_{B} of the light-emitting region E of the third sub-pixel 1023 in the second direction X. In some embodiments, a projection of the light-emitting region E of the second sub-pixel 1022 in the first direction Y is overlapped with a projection of the light-emitting region E of the first sub-pixel 1021 in the first direction Y and a projection of the light-emitting region E of the third sub-pixel 1023 in the first direction Y, and at least a portion of the light-emitting region E of the first sub-pixel 1021 and at least a portion of the light-emitting region E of the third sub-pixel 1023 are exposed.

In FIG. 13, the second sub-pixel 1022 and the third sub-pixel 1023 are in the same row, and the first sub-pixel 1021 is in a separate row, which is convenient to set the size L_{R} of the light-emitting region E of the first sub-pixel 1021 in the second direction X to be larger than the size LG of the light-emitting region E of the second sub-pixel 1022 in the second direction X and the size L_{B} of the light-emitting region E of the third sub-pixel 1023 in the second direction X. In this manner, the opening of the first sub-pixel 1022 can be maximized to reduce the decrease in the aperture ratio due to the splitting of the first sub-pixel 1022 into a plurality of light-emitting regions E, thereby increasing the lifespan of the first sub-pixel 1022.

In some embodiments, in the above display substrate provided by embodiments of the present disclosure, as shown in FIG. 2, in the sub-pixel 102 including a plurality of light-emitting regions E, the plurality of light-emitting regions E of the sub-pixel 102 are arranged side-by-side and isolated from each other in the first direction Y to obtain a better anti-peeping effect in the first direction Y. For example, in the first sub-pixel 1021, two light-emitting regions E labeled as E_{R-1} and E_{R-2}, respectively, are arranged side-by-side and isolated from each other in the first direction Y. In the second sub-pixel 1022, two light-emitting regions E labeled as E_{G-1} and E_{G-2}, respectively, are arranged side-by-side and isolated from each other in the first direction Y.

In some embodiments, in the above display substrate provided by embodiments of the present disclosure, as shown in FIG. 1 and FIGS. 9-13, sub-pixels 102 in a row along the second direction X each includes a plurality of light-emitting regions E of the same quantity; exemplarily, FIGS. 1, 9, and 11-12 illustrate that each of the second sub-pixels 1022 in the row along the second direction X includes two light-emitting regions E labeled as E_{G-1} and E_{G-2}, respectively; FIG. 10 illustrates that for the sub-pixels 102 in the row along the second direction X, first sub-pixels 1021 and second sub-pixels 1022 are arranged alternately, and each first sub-pixel 1021 includes two light-emitting regions E labeled as E_{R-1} and E_{R-2}, respectively, and each second sub-pixel 1022 includes two light-emitting regions E labeled as E_{G-1} and E_{G-2}, respectively; FIG. 11 and FIG. 13 illustrate that each of the first sub-pixels 1021 in a row along the second direction X includes two light-emitting regions E labeled as E_{R-1} and E_{R-2}, respectively. In this case, continuing to refer to FIG. 1 and FIGS. 9-13, it can be seen that the plurality of light-shielding structures 104 may include a plurality of first light-shielding structures 1041, and orthographic projections of the first light-shielding structures 1041 on the substrate 101 are arranged continuously along the second direction X between the respective light-emitting regions E of the sub-pixels 102 in the row. This not only allows the first light-shielding structures 1041 to achieve a better anti-peeping effect against the light-emitting regions E inside the sub-pixels 102 in the first direction Y, but also allows the first light-shielding structures 1041 to have a strip-like structure that is continuously arranged between the light-emitting regions E inside the sub-pixels 102, and the fabrication process is simpler.

In some embodiments, in the above display substrate provided by embodiments of the present disclosure, as illustrated in FIGS. 1, 9, and 13, in sub-pixels 102 in a row along the second direction X, a part of the sub-pixels 102 each includes multiple light-emitting regions E of the same quantity, and the rest of the sub-pixels 102 in the row each includes one light-emitting region E. Specifically, FIG. 1 and FIG. 9 illustrate that for the sub-pixels 102 in the row along the second direction X, each first sub-pixel 1021 includes two light-emitting regions E labeled as E_{R-1} and E_{R-2}, respectively, and each third sub-pixel 1023 includes one light-emitting region E labeled as EB; for the sub-pixels 102 in the row along the second direction X shown in FIG. 13, each second sub-pixel 1022 includes two light-emitting regions E labeled as E_{G-1} and E_{G-2}, respectively, and each third sub-pixel 1023 includes one light-emitting region E labeled as EB. Optionally, in FIGS. 1, 9, and 13, the plurality of light-shielding structures 104 may also include a plurality of second light-shielding structures 1042, and an orthographic projection of the second light-shielding structure 1042 on the base substrate 101 extends in the second direction X between respective light-emitting regions E of the part of the sub-pixels 102 (e.g., the first sub-pixels 1021 or the second sub-pixels 1022) in the row, to achieve a better anti-peeping effect in the first direction Y for the light-emitting regions E inside the part of sub-pixels 102 (e.g., the first sub-pixel 1021 or the second sub-pixel 1022) through the second light-shielding 1042; and because only one light-emitting region E exists in each of the rest of the sub-pixels 102 (e.g., the third sub-pixel 1023), resulting in the second light-shielding structure 1042 is disconnectedly arranged at regions where the rest of the sub-pixels 102 (e.g., the third sub-pixel 1023) are located, that is, the second light-shielding structure 1042 is not present in the regions where the rest of the sub-pixels 102 (e.g., the third sub-pixel 1023) are located.

In some embodiments, in the above display substrate provided by embodiments of the present disclosure, as shown in FIG. 1 and FIGS. 9 to 13, the sub-pixels 102 are arranged in an array, the plurality of light-shielding structures 104 includes a plurality of third light-shielding structures 1043, and orthographic projections of the third light-shielding structures 1043 on the base substrate 103 are arranged continuously in a second direction X between adjacent sub-pixels 102, in other words, the third light-shielding structure 1043 is arranged at a gap extending along the second direction X between the sub-pixels 102, and the third light-shielding structure 1043 has a strip-like structure. This setting method allows the third light-shielding structure 1043 to achieve a better anti-peeping effect against the light-emitting region E between the sub-pixels 102 in the first direction Y. At the same time, the pattern of the third light-shielding structure 1043 with the strip-like structure is simpler, which is convenient for simplifying the fabrication process.

It is to be noted that the better anti-peeping effect can be realized in the case that the first light-shielding structure 1041, the second light-shielding structure 1042, and the third light-shielding structure 1043 each satisfies the condition of having a first distance a from an adjacent light-emitting region(s) E in the first direction Y. Therefore, in some practical products, as long as the first light-shielding structure 1041, the second light-shielding structure 1042, and the third light-shielding structure 1043 each has the first distance a from the adjacent light-emitting region E in the first direction Y, there is no need to particularly consider the relationship between the widths and sizes of the first light-shielding structure 1041, the second light-shielding structure 1042, and the third light-shielding structure 1043.

Exemplarily, a width of a light-shielding structure between light-emitting regions with the same color is less than a width of a light-shielding structure between light-emitting regions with different colors. For example, FIG. 2 of the present disclosure illustrates that the width of the first light-shielding structure 1041 is substantially equal to the width of the second light-shielding structure 1042, and the width of the first light-shielding structure 1041 is less than the width of the third light-shielding structure 1043. For example, the width of the third light-shielding structure 1043 is substantially equal to the sum of the width of the first light-shielding structure 1041 and the width of the second light-shielding structure 1042. However, in specific embodiments, it is not limited to the above width and size relationships. In addition, in the embodiments provided by the present disclosure, due to the limitation of process conditions or the influence of other factors such as measurement, the “substantially equal” may be exactly equivalent or may have some deviation, so the relationship of “substantially equal” between the above features falls within the scope of protection of the present disclosure as long as an error (e.g., a 10% fluctuation up or down) is allowed.

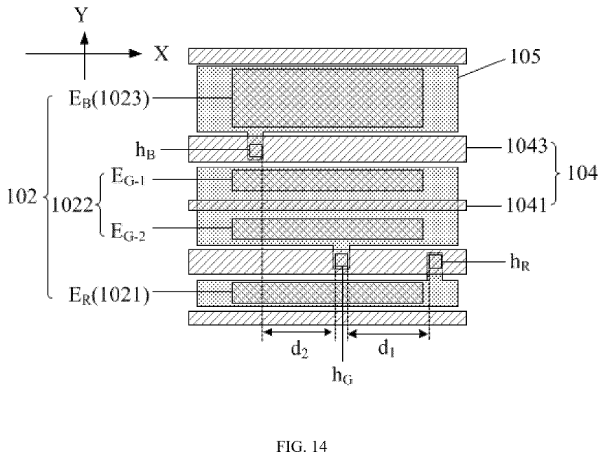

In some embodiments, in the above display substrate provided by embodiments of the present disclosure, the sub-pixel 102 may further include a pixel circuit and a light emitting element, and there is an insulating layer between a layer where the pixel circuit is located and a layer where the light emitting element is located; in the same sub-pixel 102, the pixel circuit is electrically connected with the light emitting element through a via hole that penetrates through the insulating layer; optionally, as illustrated in FIG. 14, orthographic projections of via holes labeled as h_{R}, h_{G}, and H_{B}, respectively, on the base substrate 101 are located within an orthographic projection of the third light-shielding structure 1043 on the base substrate 101. It is noted that for one sub-pixel 102, an orthographic projection of its pixel circuit on the base substrate 101 and the light-emitting region E may or may not be overlapped, and the pixel circuit may be moved slightly at will, as long as the wiring conditions are met. In the case where one sub-pixel 102 includes a plurality of light-emitting regions E, the plurality of light-emitting regions E of the sub-pixel 102 are controlled by the same pixel circuit to be turned on or off at the same time.

In some embodiments, the pixel circuit may include a plurality of transistors (TFTs) and at least one capacitor (C), for example, the pixel circuit may be a 3T1C structure, a 7T1C structure, a 5T1C structure, an 8T1C structure, or an 8T2C structure, etc., herein “T” in the above circuit structure refers to a thin-film transistor and “C” refers to a capacitor, and the number in front of “T” represents the quantity of thin film transistors in the circuit, and the number in front of “C” represents the quantity of capacitors in the circuit.

In some embodiments, the transistor may be a P-type transistor, an N-type transistor, a bottom-gate transistor, a top-gate transistor, a double-gate transistor, an amorphous silicon transistor, a low-temperature polycrystalline silicon transistor, an oxide transistor, and the like, and is not limited herein. The materials of the gate, source, and drain of the transistor may include molybdenum (Mo), aluminum (Al), titanium (Ti), chromium (Cr), nickel (Ni), and other metals; the source and drain may be a single-layer structure or a stacked-layer structure, for example, the source and drain may be a stacked-layer structure composed of a titanium metal layer/aluminum metal layer/titanium metal layer; the materials of the gate may include molybdenum (Mo), aluminum (Al), titanium (Ti), chromium (Cr), nickel (Ni), and other metals, and the gate may be a single-layer structure or a stacked-layer structure, for example, the gate is a single-layer structure composed of a molybdenum metal layer.

The light emitting element may be configured to emit light of a corresponding brightness in response to a drive current output by a pixel circuit of the sub-pixel in which the light emitting element is located. For example, the light emitting element may be an organic light-emitting diode (OLED) which may include a first pole 105 (e.g., anode), a light-emitting function layer 106, and a second pole 108 (e.g., cathode) that are stacked. However, the present embodiments are not limited in this regard. For example, the light emitting element may be a Micro Light Emitting Diode (Micro-LED,), or a Mini Light Emitting Diode (Mini-LED), or a Quantum Dot Light Emitting Diode (QLED).

In some embodiments, in the above display substrate provided by embodiments of the present disclosure, as shown in FIG. 14, the first pole 105 (e.g., anode) is integrally arranged within the sub-pixel 102, in other words, a sub-pixel 102 may include one or more than one light-emitting regions E, but the sub-pixel 102 has only one intact first pole 105 (e.g., anode), and in a case of one sub-pixel 102 including multiple light-emitting regions E, the multiple light-emitting regions E in the sub-pixel 102 share the same one first pole 105 (e.g., anode). For example, in FIG. 14, two light-emitting regions E labeled as E_{G_1} and E_{G_2}, respectively, in one second sub-pixel 1022 share the same one first pole 105 (e.g., anode). In some embodiments, the first pole 105 (e.g., anode) shared by the two light-emitting regions E labeled as E_{G_1} and E_{G_2}, respectively, in one second sub-pixel 1022 is connected with the same one pixel circuit, such that one pixel circuit can be employed to control the two light-emitting regions E labeled as E_{G_1} and E_{G_2}, respectively, to be turned on or off simultaneously.

Continuing to refer to FIG. 14, it can be seen that in some embodiments, first poles 105 (e.g., anodes) of the first sub-pixel 1021, the second sub-pixel 1022, and the third sub-pixel 1023 are substantially equal in length in the second direction X. An orthographic projection of a first via hole h_{R} between the first pole 105 (e.g., anode) of the first sub-pixel 1021 and a corresponding pixel circuit on the base substrate 101, and an orthographic projection of a second via hole h_{G} between the first pole 105 (e.g., anode) of the second sub-pixel 1022 and a corresponding pixel circuit on the base substrate 101 are both located within an orthographic projection of the third-shielding structure 1043 located between the first sub-pixel 1021 and the second sub-pixel 1022 on the base substrate 101. An orthographic projection, on the base substrate 101, of the third via hole hp between the first pole 105 (e.g., anode) of the third sub-pixel 1023 and a corresponding pixel circuitry is located within an orthographic projection, on the base substrate 101, of the third-shielding structure 1043 between the third sub-pixel 1023 and the second sub-pixel 1022.

In some embodiments, in order to avoid affecting the light emission, as shown in FIG. 14, orthographic projections of the first via hole h_{R} and the second via hole h_{G} on the base substrate 101 may be located between a region in which the first sub-pixel 1021 is located and a region in which the second sub-pixel 1021 is located, and the first via hole h_{R} and the second via hole h_{G} are roughly in the same straight line; optionally, the first via hole h_{R}, the second via hole h_{G}, and the third via hole h_{B} are all arranged outside the light-emitting region, and the first via hole h_{R}, the second via hole h_{G}, and the third via hole h_{B} are sequentially staggered in the second direction X. For example, a spacing d₁ between the first via hole h_{R} and the second via hole h_{G} is smaller than a spacing d₂ between the second via hole h_{G} and the third via hole h_{B}. In other embodiments, in the second direction X, an overlapping area between a projection of the first via hole h_{R} and a projection of a corresponding light-emitting region, an overlapping area between a projection of the second via hole h_{G} and a projection of a corresponding light-emitting region, and an overlapping area between a projection of the third via hole h_{B} and a projection of a corresponding light-emitting region are different: for example, the first via hole h_{R} is outside its corresponding light-emitting region labeled as E_{R} (i.e., the projection of the first via hole h_{R} in the second direction X is staggered from the projection of its corresponding light-emitting region labeled as E_{R} in the second direction X); a projection of the second via hole h_{G} in the second direction X is substantially in the middle region of projections of the light-emitting regions labeled as E_{G-1}, E_{G-2}, respectively, in the second direction X; and a projection of the third via hole h_{B} in the second direction X is substantially in an edge region of a projection of the light-emitting region labeled as EB in the second direction X.

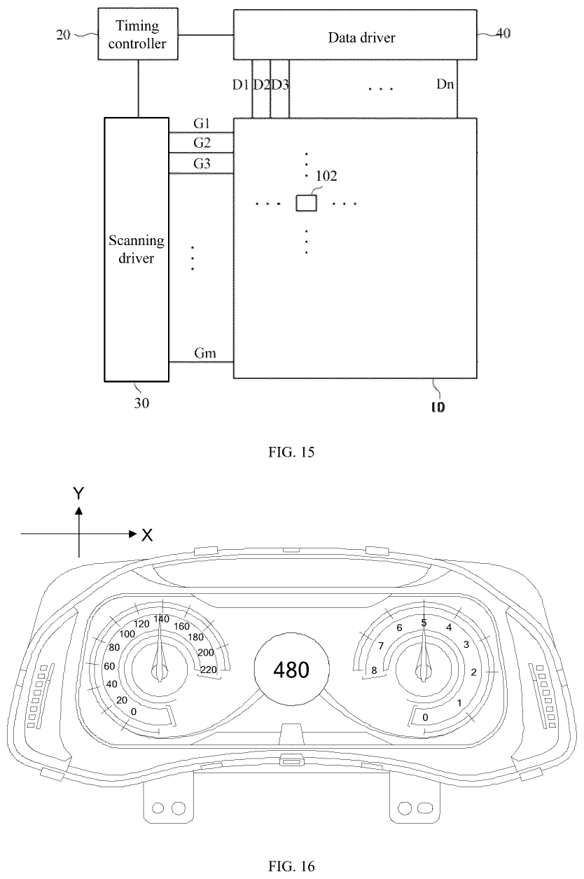

In some embodiments, the above display substrate provided by embodiments of the present disclosure, as shown in FIG. 15, may further include: a timing controller 20, a data driver 40, a gate drive circuit, and a sub-pixels array 10. The gate drive circuit may include at least one driver, such as a scanning driver 30. The timing controller 20, the data driver 40, and the gate drive circuit may be disposed at a peripheral region at the periphery of a display region of the display substrate. The sub-pixels array 10 disposed in the display region may include a plurality of sub-pixels 102 arranged in regular arrangement. The scanning driver 30 may be configured to provide scanning signals to the sub-pixels 102 through scan lines; the data driver 40 may be configured to provide data signals to the sub-pixels 102 through data lines; and the timing controller 20 may be configured to control the scanning driver 30 and the data driver 40.

In some embodiments, the timing controller 20 may provide grayscale values and control signals suitable for the specifications of the data driver 40 to the data driver 40; the timing controller 20 may provide clock signals, initial signals, and the like suitable for the specifications of the scanning driver 30 to the scanning driver 30. The data driver 40 may utilize the grayscale values and control signals received from the timing controller 20 to generate data voltages that will be supplied to the data lines D1 to Dn. For example, the data driver 40 may sample the grayscale value using the clock signal and apply a data signal corresponding to the grayscale value to the data lines D1 to Dn in units of sub-pixel rows. The scanning driver 30 may generate a scanning signal that will be supplied to the scan lines G1 to Gm by using the clock signal, the initial signal, and the like received from the timing controller 20. For example, the scanning driver 30 may sequentially provide the scanning signals having conduction level pulses to the scan lines. In some embodiments, the scanning driver 30 may include a shift register that may generate the scanning signals in a manner that sequentially transmits the scanning initial signals supplied in the form of conduction level pulses to the next level of circuit under the control of a clock signal. Herein, n and m are natural numbers.

In some embodiments, the gate drive circuit may be provided directly on the base substrate 101. For example, the gate drive circuit may be arranged in a peripheral region on the left and right sides of the display region. In some embodiments, the gate drive circuit may be formed with the sub-pixels 102 in a process for forming the sub-pixels 102. However, this embodiment is not limited as to the location or formation method of the gate drive circuit. In some embodiments, the gate driver circuit may be arranged on a separate chip or printed circuit board to be attached to pads or welding pad formed on the base substrate 101.

In some embodiments, the data driver 40 may be arranged on a separate chip or printed circuit board, to connect with the sub-pixel 102 via signal access pins arranged on the base substrate 101. For example, the data driver 40 may be arranged using a packaging technology such as chip-on-glass (COG), chip-on-plastic (COP), chip-on-film (COF), or the like, to connect with the signal access pins on the base substrate 101. The timing controller 20 may be arranged separately from the data driver 40 or integrally arranged with the data driver 40. However, this is not limited by the embodiments.

In some embodiments, the above display substrate provided by embodiments of the present disclosure may also include a protective cover plate located on a side of a layer where the plurality of light-shielding structures 104 are located away from the substrate 101, etc., and other indispensable components of the display substrate should be understood by a person of ordinary skill in the art, and will not be repeated herein, and should not be used as a limitation of the present disclosure.

Based on the same inventive concept, embodiments of the present disclosure provide a display apparatus including the above display substrate provided by embodiments of the present disclosure. Optionally, the display apparatus is the instrument panel shown in FIG. 16, with the anti-peeping direction being a vertical direction. By adopting the above display substrate provided by the embodiments of the present disclosure, the large viewing angle outgoing light in the vertical direction can be effectively prevented from being irradiated onto the front windshield, and the influence of the reflected light on the driver's vision can be avoided. In addition, it should be understood that the above display apparatus provided by the embodiments of the present disclosure may not only be the above instrument panel, but also, for example, a display product such as a navigator that may need require peep-shielding, and the present disclosure is not specifically limited.

In other embodiments, the display apparatus provided by embodiments of the present disclosure may further include, but is not limited to, components such as: a network module, an interface unit, and a control chip. Optionally, the control chip is a central processor, a digital signal processor, a system-on-chip (SoC), and the like. For example, the control chip may also include a memory, and may also include a power supply module and the like, and the power supply as well as the signal input and output functions are realized through additionally provided wires, signal lines, and the like. For example, the control chip may also include a hardware circuit, codes that can be executed by a computer, and the like. The hardware circuit may include a conventional Very Large Scale Integration (VLSI) circuit or a gate array as well as an existing semiconductor such as a logic chips, a transistor, and other discrete components; the hardware circuit may also include a field programmable gate array, a programmable array logic, a programmable logic device, and the like. In addition, it is understood by those skilled in the art that the above structure does not constitute a limitation of the above display apparatus provided by the embodiments of the present disclosure; in other words, more or fewer of the above components, or combinations of some of the components, or different arrangements of the components may be included in the above display apparatus provided by the embodiments of the present disclosure.

Based on the same inventive concept, embodiments of the present disclosure provide a manufacturing method of the above display substrate, as shown in FIG. 17, which may include the following steps.

S1701, providing a base substrate.

S1702, forming a plurality of sub-pixels arranged on the base substrate in an array, where at least one sub-pixel includes at least two light-emitting regions, light-emitting regions of different sub-pixels are arranged in isolation in a first direction and a second direction, respectively, and the first direction is an anti-peeping direction and the second direction is perpendicular to the first direction.

In some embodiments, an opening of a pixel definition layer corresponding to one sub-pixel may be divided into at least two sub-openings, and a light-emitting material layer in the sub-pixel may be disconnected at a gap between the sub-openings of the pixel definition layer, thereby forming at least two light-emitting regions within the sub-openings of the pixel definition layer.

S1703, forming a plurality of light-shielding structures on a side of a layer where the plurality of sub-pixels are located away from the base substrate, and such that an orthographic projection of the light-shielding structure on the base substrate extends in the second direction between adjacent light-emitting regions and ensuring that the orthographic projection of the light-shielding structure on the base substrate has a first distance from a corresponding light-emitting region in the first direction.

It is to be noted that in the above manufacturing method provided by the embodiments of the present disclosure, the composition process involved in forming the various layer structures may include not only some or all of the process processes of deposition, photoresist coating, mask template masking, exposure, developing, etching, photoresist stripping, etc., but also other process processes, which are based on the formation of the graphic of the desired composition during the actual fabrication process, and will not be limited herein. For example, a post-baking process may also be included after developing and before etching. Among them, the deposition process can be a chemical vapor deposition method, a plasma enhanced chemical vapor deposition method or a physical vapor deposition method, without limitation herein; the mask used in the masking process can be a Half Tone Mask, a single slit diffraction mask (Single Slit Mask) or a Gray Tone Mask, without limitation herein; the etching can be dry etching or wet etching, which is not limited herein.

Although the preferred embodiments of the present disclosure have been described, those skilled in the art will be able to make additional changes and modifications to these embodiments once the basic inventive concepts are apparent. Therefore, it is intended that the appended claims be construed to include the preferred embodiments and all changes and modifications that fall within the scope of the present disclosure.

Obviously, those skilled in the art can make various changes and modifications to the embodiments of the present disclosure without departing from the spirit and scope of the embodiments of the present disclosure. In this way, if these modifications and variations of the embodiments of the present disclosure fall within the scope of the claims of the present disclosure and equivalent technologies, the present disclosure is also intended to include these modifications and variations.

1-20. (canceled)

21. A display substrate, comprising:
a base substrate;
a plurality of sub-pixels arranged on the base substrate in an array; wherein at least one of the sub-pixels comprises at least two light-emitting regions, light-emitting regions of different sub-pixels are arranged in isolation in a first direction and in a second direction, respectively, the first direction is an anti-peeping direction, and the second direction is perpendicular to the first direction;
a plurality of light-shielding structures, arranged at a light emitting side of the plurality of sub-pixels, wherein an orthographic projection of the light-shielding structure on the base substrate extends along the second direction between adjacent light-emitting regions, and the orthographic projection of the light-shielding structure on the base substrate has a first distance from at least one of the adjacent light-emitting regions in the first direction.

22. The display substrate according to claim 21, wherein different sub-pixels in a part of the sub-pixels comprise different quantities of light-emitting regions.

23. The display substrate according to claim 21, wherein, the at least two light-emitting regions in the at least one of the sub-pixels are arranged side by side and isolated from each other in the first direction.

24. The display substrate according to claim 21, wherein,
sub-pixels in a row along the second direction each comprises a same quantity of light-emitting regions; and
the plurality of light-shielding structures comprises a plurality of first light-shielding structures, and orthographic projections of the first light-shielding structures on the base substrate are continuously arranged in the second direction between light-emitting regions of the sub-pixels in the row.

25. The display substrate according to claim 21, wherein,
a part of sub-pixels in a row along the second direction each comprises multiple light-emitting regions of a same quantity, and the rest of the sub-pixels in the row each comprises one light-emitting region;
the plurality of light-shielding structures comprises a plurality of second light-shielding structures, and an orthographic projection of the second light-shielding structure on the base substrate extends in the second direction between light-emitting regions of the part of sub-pixels in the row, and is disconnectedly arranged at regions where the rest of the sub-pixels are located.

26. The display substrate according to claim 21, wherein the plurality of light-shielding structures comprises a plurality of third light-shielding structures, and orthographic projections of the third light-shielding structures on the base substrate are continuously arranged in the second direction between adjacent sub-pixels.

27. The display substrate according to claim 26, wherein the sub-pixel further comprises a pixel circuit and a light emitting element, an insulating layer is disposed between a layer where the pixel circuit is located and a layer where the light emitting element is located; and
in the sub-pixel, the pixel circuit is electrically connected with the light emitting element through a via hole penetrating through the insulating layer; wherein an orthographic projection of the via hole on the base substrate is within the orthographic projection of the third light-shielding structure on the base substrate.

28. The display substrate according to claim 21, wherein in a plurality of light-emitting regions of a same sub-pixel, at least part of the light-emitting regions have substantially a same size in the first direction; and
in different sub-pixels each comprising a plurality of light-emitting regions, at least two light-emitting regions of different sub-pixels have substantially a same size in the first direction.

29. The display substrate according to claim 21, wherein, a light-emitting region of a sub-pixel comprising only the light-emitting region has a size in the first direction that is greater than a size, in the first direction, of a light-emitting region of a sub-pixel comprising a plurality of light-emitting regions.

30. The display substrate according to claim 21, wherein a quantity of light-emitting regions of one sub-pixel is greater than a quantity of light-emitting regions of another sub-pixel, and wherein a color of light emitted by the one sub-pixel is different from a color of light emitted by the another sub-pixel.

31. The display substrate according to claim 30, wherein,
the plurality of sub-pixels comprises a plurality of first sub-pixels, a plurality of second sub-pixels, and a plurality of third sub-pixels, and luminous brightness of the first sub-pixels and luminous brightness of the second sub-pixels each is greater than luminous brightness of the third sub-pixels; and
the first sub-pixel and/or the second sub-pixel each comprises a plurality of the light-emitting regions, and the third sub-pixel comprises one light-emitting region.

32. The display substrate according to claim 31, wherein one of the first sub-pixel and the second sub-pixel is arranged alternately with the third sub-pixel in the second direction, and a row where the other one of the first sub-pixel and the second sub-pixel is located and a row where the third sub-pixel is located are arranged alternately in the first direction.

33. display substrate according to claim 32, wherein, among the first sub-pixel, the second sub-pixel and the third sub-pixel, a size, in the second direction, of a light-emitting region of the first sub-pixel or the second sub-pixel in a separate row is larger than a size, in the second direction, of a light-emitting region of each of the remaining two sub-pixels.

34. The display substrate according to claim 31, wherein,
the first sub-pixels are arranged alternately with the second sub-pixels in the second direction, and rows in which the first sub-pixels are located are arranged alternately in the first direction with rows in which the third sub-pixels are located; or
rows in which the first sub-pixels are located, rows in which the second sub-pixels are located, and rows in which the third sub-pixels are located are arranged alternately and cyclically in the second direction.

35. The display substrate according to claim 31, wherein the first sub-pixel is a red sub-pixel, the second sub-pixel is a green sub-pixel, and the third sub-pixel is a blue sub-pixel.

36. The display substrate according to claim 21, wherein the sub-pixel further comprises an anode, and the anode is integrally arranged within the sub-pixel.

37. The display substrate according to claim 36, wherein the sub-pixel further comprises a light emitting material layer on a side of the anode away from the base substrate, and the light emitting material layer is disconnectedly arranged between a plurality of light-emitting regions in the sub-pixel.

38. The display substrate according to claim 37, further comprising a pixel definition layer between a layer where the anode is located and the light emitting material layer, wherein the pixel definition layer comprises a plurality of openings, and regions where the openings are located are the light-emitting regions.

39. A display apparatus, comprising a display substrate according to claim 21, wherein the display apparatus comprises an instrument panel, and the anti-peeping direction is a vertical direction.

40. A manufacturing method of a display substrate, comprising:
providing a base substrate;
forming a plurality of sub-pixels arranged on the base substrate in an array; wherein at least one of the sub-pixels comprises at least two light-emitting regions, light-emitting regions of different sub-pixels are arranged in isolation in a first direction and a second direction, respectively, and the first direction is an anti-peeping direction, and the second direction is perpendicular to the first direction;
forming a plurality of light-shielding structures on a side of a layer where the plurality of sub-pixels are located away from the base substrate; wherein an orthographic projection of the light-shielding structure on the base substrate extends in the second direction between adjacent the light-emitting regions, and the orthographic projection of the light-shielding structure on the base substrate has a first distance from at least one of the adjacent light-emitting regions in the first direction.
